(19) United States
(12) Patent Application Publication
(10) Pub. No.: US 2011/0032135 A1
(43) Pub. Date: Feb. 10, 2011

(54) D/A CONVERTER

(75) Inventor: Fumio Tonomura, Kanagawa (JP)

Correspondence Address: SUGHRUE MION, PLLC, 2100 PENNSYLVANIA AVENUE, N.W., SUITE 800, WASHINGTON, DC, 20037, US

(73) Assignee: NEC Electronics Corporation, Kawasaki (JP)

(21) Appl. No.: 12/827,471

(22) Filed: Jun. 30, 2010

(30) Foreign Application Priority Data
Aug. 7, 2009 (JP) 2009-185013

(51) Int. Cl. H03M 1/76

(52) U.S. Cl. 341/148

(57) ABSTRACT

A D-A converter includes a resistor string that generates a plurality of voltages including an upper limit voltage, a lower limit voltage, and an intermediate voltage, a first selector that selects and outputs a first voltage among the plurality of voltages according to a lower bit, the first voltage being selected from the intermediate voltage and a voltage lower than the intermediate voltage, a second selector that selects and outputs a second voltage according to a higher bit, the second voltage being one of a lower power supply voltage and the intermediate voltage or a voltage higher than the intermediate voltage, a third selector that selects and outputs a third voltage according to the higher bit, the third voltage being selected from the lower limit voltage and the lower power supply voltage; and an amplifier that adds the first voltage and the second voltage and subtracts the third voltage.

### INCORPORATION BY REFERENCE

This application is based upon and claims the benefit of priority from Japanese patent application No. 2009-185013, filed on Aug. 7, 2009, the disclosure of which is incorporated herein in its entirety by reference.

### BACKGROUND

1. Field of the Invention

The present invention relates to a D-A converter, and more specifically, to a resistor string/switching tree type D-A converter.

2. Description of Related Art

Liquid crystal display panels used in portable telephones, digital cameras and the like have been increasing in size (narrow frame area), and now use larger number of colors (multi-gradation) from 260,000 colors (6-bit RGB) to 16,770,000 colors (8-bit RGB). In addition, the voltage used in the liquid crystal display panels has been decreasing.

The advancement of techniques of multi coloring and low voltage in the liquid crystal panel decreases a liquid crystal applied voltage per one gradation. In summary, since the difference between adjacent gradation levels becomes smaller, even minor deviation of the liquid crystal applied voltage greatly affects the image quality.

Now, a flicker, which is one of phenomena caused in the image display, will be considered with a liquid crystal display panel employing a line inversion display method in which a source output and a common output are inverted for each line. FIG. 5 shows source and common output waveforms. The potential difference between a source output 20 and a common output 21 is applied to a liquid crystal. In the line inversion display method, polarities of the source output 20 and the common output 21 are inverted for every one line.

The color and the flicker are optimally adjusted by adjusting an amplitude 23 of a common voltage and a common center voltage (DC value) 22. The steps of adjusting the voltages need to be decreased with decreasing liquid crystal applied voltage for one gradation.

As shown in FIG. 6, the amplitude 23 of the common voltage is generated in a D-A converter 13 in a liquid crystal display panel driving IC11, and the center voltage 22 is generated in a D-A converter 14. Thus, a multi-color and low-voltage liquid crystal display panel driving IC is required to include a multi-bit D-A converter that is able to set the amplitude 23 of the common voltage and the center voltage (DC value) 22 with fewer steps. Although seven bits were sufficient before, eight or more bits have now been required. In addition, further downsizing has been required to narrow the area of the frame and to reduce cost.

FIG. 7 is a resistor string/switching tree type 3-bit D-A converter based on a reference voltage generator disclosed in Japanese Unexamined Patent Application Publication No. 1-175308 (Katayose). For the sake of simplicity, the circuit shown in FIG. 7 has smaller number of bits than an actual common voltage generating D-A converter.

The D-A converter includes a resistor string 90, a selector 91, and an amplifier 92. The resistor string 90 generates desired upper limit voltage VTOP32 and lower limit voltage VBTM40 from a reference voltage VREF31, and evenly divides voltage between the upper limit voltage and the lower limit voltage by eight, so as to obtain voltages V33 to V39. The selector 91 selects the analog voltages V33 to V39 taken out from the resistor string 90 according to digital input data D[2:0], and outputs the selected voltage as an analog voltage V41. The amplifier 92 amplifies (doubles in this circuit) the analog voltage V41 that is selected, and outputs the amplified voltage as an output voltage VOUT47.

The selector 91 includes switches SW50 to SW63 arranged in a tournament manner. Only one path of the selector 91 is ON by digital input data D[2:0], and the analog voltage V41 is output. The amplifier 92 includes an operational amplifier AMP74 and resistors R80 and R81. The amplification ratio of the amplifier 92 is determined by the resistors R80 and R81.

The operation when the reference voltage VREF31=5V and digital data D[2:0]=(1, 0, 0) is as follows. By dividing the reference voltage VREF31 by the resistor string 90, the upper limit voltage VTOP32 and the lower limit voltage VBTM40 are generated. Voltages V33 to V39, which are obtained by evenly dividing voltage between the upper limit voltage VTOP32 and the lower limit voltage VBTM40 by eight, are drawn out from each tap.

The resistor string 90 includes 10 resistors. Assume that each of the resistors has a value as shown in FIG. 7. Then, the upper limit voltage VTOP32, the lower limit voltage VBTM40, and the voltage step VSTEP are shown as follows.

VTOP32=(5.5·R)/(10·R)×5 V=2.75 V

VBTM40=(1.5·R)/(10·R)×5 V=0.75 V

VSTEP=(VTOP32−VBTM40)/8=2 V/8=0.25 VWhen D[2:0]=(1, 0, 0) is input, SW50, SW52, SW54, SW56, SW58, SW60, SW63 are ON, SW51, SW53, SW55, SW57, SW59, SW61, SW62 are OFF, and voltage V35 is selected and output as the analog voltage V41. The analog voltage V41 is amplified and doubled by the amplifier 92 and is output as the output voltage VOUT47.

The analog voltage V41 and the output voltage VOUT47 can be obtained from the following expressions.

V41=VBTM40+VSTEP×5=0.75+0.25×5=2.0V

VOUT47=V41×2=2.0V×2=4.0 V When the digital input data is D[2:0]=(0, 0, 0) to (1, 1, 1), the output voltage VOUT47 can be expressed as follows.

VOUT47=(VBTM+VSTEP×(n+1))×2(n=0 to 7)

FIG. 8 shows the analog voltage V41 and the output voltage V47 corresponding to the digital input data.

Further, in the m-bit D-A converter, the following expressions can be obtained.

VSTEP=(VTOP−VBTM)/2^{m}

VOUT=(VBTM+VSTEP×(n+1))×2 (n=0 to 2^{m}−1)

As discussed above, a multi-color and low-voltage liquid crystal display panel driving IC is required to include a multi-bit D-A converter which is able to set the common voltage with fewer steps. In the circuit shown in FIG. 7, the analog voltage generated in the resistor string is selected by the switches arranged in a tournament manner according to the digital input data. Therefore, the increase in the number of bits causes increase in the number of switches of the voltage selector. This leads to a larger chip size, which makes it difficult to narrow the area of the frame and to reduce cost. In the m-bit D-A converter, the number of switches of the voltage selector is expressed by the following expression.

2^{m}+2^{(m-1)}+2^{(m-2)}+ . . . +2¹

For example, the number of switches is 254 in the 7-bit D-A converter, and 510 in the 8-bit D-A converter. The difference between them is 256, which means the area of the voltage selector in the 8-bit D-A converter is twice as large as that in the 7-bit D-A converter.

### SUMMARY

The present inventors have found a problem that the resistor string/switching tree type D-A converter based on the reference voltage generator disclosed in Katayose increases the number of switches with the increase of the number of bits, thereby increasing the size.

A first exemplary aspect of the invention is a D-A converter including a resistor string, a first selector, an amplifier, a second selector, and a third selector. The resistor string generates a plurality of voltages including an upper limit voltage, a lower limit voltage, and an intermediate voltage which is between the upper limit voltage and the lower limit voltage. The first selector selects and outputs a first voltage among the plurality of voltages according to a lower bit, the first voltage being selected from the intermediate voltage and a voltage lower than the intermediate voltage. The second selector selects and outputs a second voltage according to a higher bit, the second voltage being one of a lower power supply voltage and the intermediate voltage or a voltage higher than the intermediate voltage. The third selector selects and outputs a third voltage according to the higher bit, the third voltage being selected from the lower limit voltage and the lower power supply voltage. The amplifier adds the first voltage and the second voltage and subtracts the third voltage, to output an output voltage.

A second exemplary aspect of the invention is a D-A converter including a resistor string, a first selector, an amplifier, and a second selector. The resistor string generates a plurality of voltages including an upper limit voltage, a lower limit voltage, and an intermediate voltage which is between the upper limit voltage and the lower limit voltage. The first selector selects and outputs a first voltage among the plurality of voltages according to a lower bit, the first voltage being selected from the intermediate voltage and a voltage lower than the intermediate voltage. The second selector selects and outputs a second voltage according to a higher bit, the second voltage being one of a lower power supply voltage and the intermediate voltage or a voltage higher than the intermediate voltage. The amplifier adds the first voltage and the second voltage to output an output voltage. Accordingly, the number of switches of the voltage selector can be reduced, thereby obtaining the D-A converter which can save the circuit size even when multiple bits are used.

The present invention provides a D-A converter capable of suppressing the increase in the number of switches with the increase in the number of bits and suppressing the increase in size.

### BRIEF DESCRIPTION OF THE DRAWINGS

The above and other exemplary aspects, advantages and features will be more apparent from the following description of certain exemplary embodiments taken in conjunction with the accompanying drawings, in which:

FIG. 1 shows a configuration of a D-A converter according to a first exemplary embodiment;

FIG. 2 shows an analog output voltage corresponding to digital input data in the circuit shown in FIG. 1;

FIG. 3 shows a configuration of a D-A converter according to a second exemplary embodiment;

FIG. 4 shows a configuration of a D-A converter according to a third exemplary embodiment;

FIG. 5 shows output waveforms of a liquid crystal display panel driving IC;

FIG. 6 shows a configuration of the liquid crystal panel driving IC;

FIG. 7 shows a configuration of a resistor string/switching tree type D-A converter based on a reference voltage generator disclosed in Katayose; and

FIG. 8 shows an analog output voltage corresponding to digital input data in the circuit shown in FIG. 7.

### DETAILED DESCRIPTION OF THE EXEMPLARY EMBODIMENTS

### First Exemplary Embodiment

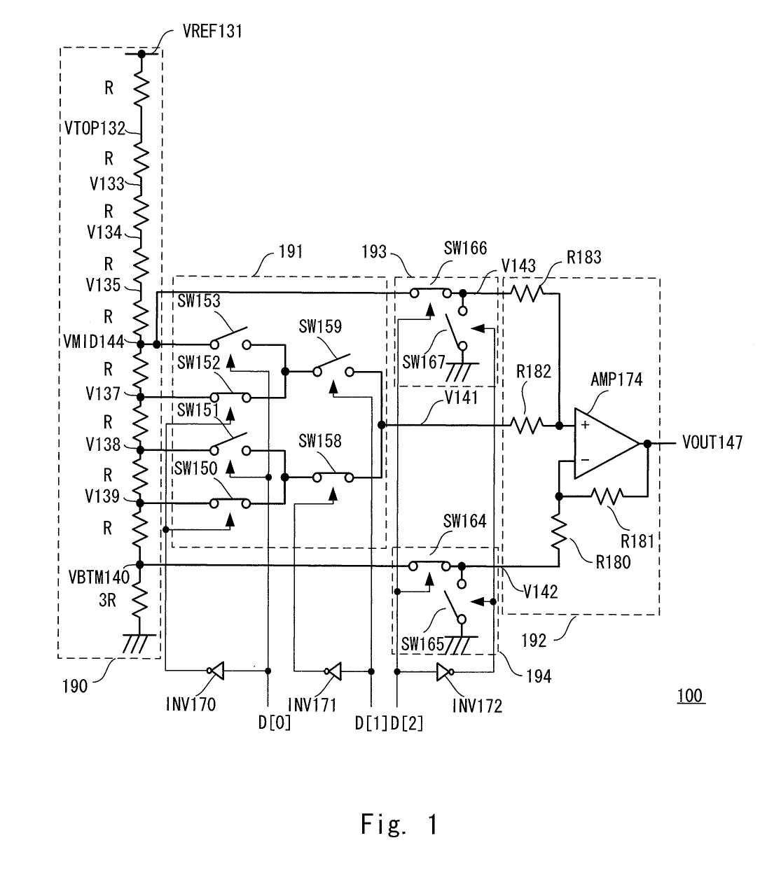

A D-A converter according to the first exemplary embodiment of the present invention will be described with reference to FIG. 1. FIG. 1 shows a configuration of a D-A converter 100 according to the first exemplary embodiment. The D-A converter 100 is a resistor string/switching tree type D-A converter. In the first exemplary embodiment, a 3-bit D-A converter 100 will be described as an example.

As shown in FIG. 1, the D-A converter 100 includes a resistor string 190, a first selector 191, an amplifier 192, a second selector 193, and a third selector 194. The resistor string 190 generates desired upper limit voltage VTOP132 and lower limit voltage VBTM140 from a reference voltage VREF131, evenly divides the voltage between the upper limit voltage and the lower limit voltage by eight, so as to obtain an intermediate voltage VMID 144, and V133 to V139.

The resistor string 190 includes 10 resistors connected in series. Note that the first and tenth resistors may have the same resistance value equal to that of the second to ninth resistors arranged between the first and tenth resistors, or may have different resistance values from that of the second to ninth resistors, or may be resistor strings.

The first resistor has one end to which the reference voltage VREF 131 is supplied. The voltage in the node between the first and the second resistors corresponds to the upper limit voltage VTOP132. The tenth resistor has one end to which ground voltage is supplied. The voltage in the node between the ninth and the tenth resistors corresponds to the lower limit voltage VBTM140.

The voltages in the respective nodes between the second to ninth resistors are V133 to V135, the intermediate voltage VMID144, and V137 to V139 in order. In short, the voltage in the node between the fifth and the sixth resistors corresponds to the intermediate voltage VMID144. In short, the intermediate voltage VMID144 is intermediate between the upper limit voltage VTOP132 and the lower limit voltage VBTM140.

In an output side of the resistor string 190, a first selector 191 is provided. The first selector 191 outputs one voltage selected from the intermediate voltage VMID144 and voltages V137 to V139 according to digital input data D[1:0] which is a lower bit to the amplifier 192 as a voltage V141. The voltage V141 is equal to or lower than the intermediate voltage VMID144.

The first selector 191 includes switches SW150 to SW159 that are arranged in a tournament manner. ON/OFF of the switches SW150 to SW159 is controlled according to the digital input data D[1:0], and only one path is ON.

The digital input data D[0] is supplied to the switches SW151 and SW153. Further, the digital input data D[0] is inverted by an inverter INV170, and then supplied to the switches SW150 and SW152. The digital input data D[1] is supplied to the switch SW159, and is also supplied to the switch SW158 after being inverted by an inverter INV171. Each of the switches is ON when the input data is “1”.

The second selector 193 is provided in an output side of the first selector 191. The second selector 193 selects the intermediate voltage VMID144 or a lower power supply voltage (0V) according to digital input data D[2] which is a higher bit, and outputs a voltage V143. The third selector 194 selects the lower limit voltage VBTM140 or the lower power supply voltage (0V) according to the digital input data D[2] which is the higher bit, and outputs a voltage V142.

The second selector 193 includes switches SW166 and SW167. The switch SW167 has one end to which the ground voltage (0V) is supplied and the other end connected to an output side of the switch SW166. The second selector 193 selects one of the intermediate voltage VMID144 and 0 V according to the digital input data D[2]. The digital input data D[2] is supplied to the switch SW166, and is also supplied to the switch SW167 after being inverted by an inverter INV172.

The third selector 194 includes switches SW164 and SW165. The switch SW165 has one end to which the ground voltage (0V) is supplied and the other end connected to an output side of the switch SW164. The third selector 194 selects one of the lower limit voltage VBTM140 and 0 V according to the digital input data D[2]. The digital input data D[2] is supplied to the switch SW164, and is also supplied to the switch SW165 after being inverted by the inverter INV172.

The amplifier 192 adds the voltage V143 output from the second selector 193 to the analog voltage V141 selected by the first selector 191, subtracts the voltage V142 output from the third selector 194, and outputs the result as an output voltage VOUT147.

The amplifier 192 includes an operational amplifier AMP174, and resistors R180, R181, R182, and R183. The resistance values of the resistors R180 to R183 are equal to each other. The resistor R180 has one end connected to an output of the third selector 194, and the other end connected to an inverting terminal of the operational amplifier AMP174. The resistor R181 is connected between the other end of the resistor R180 and an output of the operational amplifier AMP174.

The resistor R182 has one end connected to an output of the first selector 191, and the other end connected to a non-inverting input terminal of the operational amplifier AMP174. The resistor R183 is connected between an output of the second selector 193 and the other end of the resistor R182.

The operation when the reference voltage VREF131=6 V, and digital input data D[2:0]=(1, 0, 0) is given is as follows. In this example, the digital input data D[1:0] is the lower bit, and D[2] is the higher bit.

By dividing the reference voltage VREF131 by the resistor string 190, VTOP132 and VBTM140, and the intermediate voltage VMID144 are generated. Further, the voltages V133 to V139 obtained by evenly dividing voltage between VTOP132 and VBTM140 by eight are drawn out from each tap.

When the resistance values in the 10 resistors are as shown in the drawings, each voltage is calculated as follows.

VTOP132=(11·R)/(12·R)×6V=5.5 V

VBTM140=3R/(12·R)×6V=1.5 V

VSTEP=(VTOP132−VBTM140)/8=4 V/8=0.5 V

VMID144=(7·R)/(12·R)×6 V=3.5 V

When the digital input data D[2:0]=(1, 0, 0) is input, SW150, SW152, SW158 of the voltage selector 191 are ON by the lower two bits, SW151, SW153, SW159 are OFF, V139 is selected, and the following voltage V141 is output.

V141=VBTM140+VSTEP×1=1.5+0.5×1=2.0 V

The SW166 of the second selector 193 is ON and the SW167 is OFF by the higher one bit D[2], and the intermediate voltage VMID144 is output as the voltage V143. Further, the SW164 of the third selector 194 is ON and the SW165 is OFF, and the lower limit voltage VBTM140 is output as the voltage V142.

These voltages are input to the amplifier 192. The amplifier 192 adds the voltages V141 and V143, subtracts the voltage V142, and outputs the output voltage VOUT147 as follows.

VOUT147=V141+V143−V142=2.0+3.5-1.5=4.0 V

When the digital input data is D[2:0]=(0, 0, 0) to (1, 1, 1) (n=0 to 7), the output voltage VOUT147 can be expressed as follows:

$$\begin{matrix}when n = 0 to 3 , \\ V 141 = VSTEP \times ( n + 1 ) + VBTM 140 \\ V 143 = 0 , V 142 = 0 \\ \begin{matrix}VOUT 147 = V 141 + V 143 - V 142 \\ = VSTEP \times ( n + 1 ) + VBTM 140 ;\end{matrix} \\ and & 1 ) \\ when n = 4 to 7 , \\ V 141 = VSTEP \times ( n - 3 ) + VBTM 140 \\ V 143 = VMID 144 , V 142 = VBTM 140 \\ \begin{matrix}VOUT 147 = V 141 + V 143 - V 142 \\ = VSTEP \times ( n - 3 ) + VBTM 140 + VMID 144 - VBTM 140 \\ = VSTEP \times ( n - 3 ) + VMID 144.\end{matrix} & 2 )\end{matrix}$$

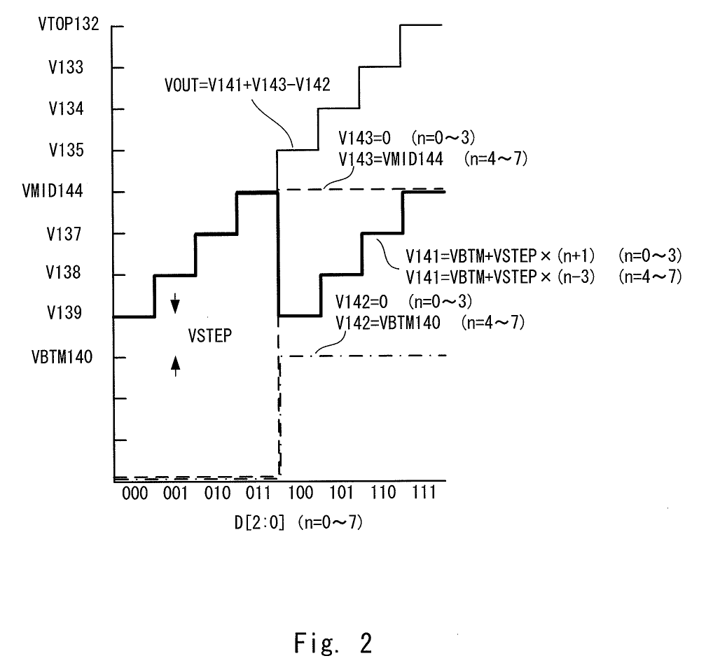

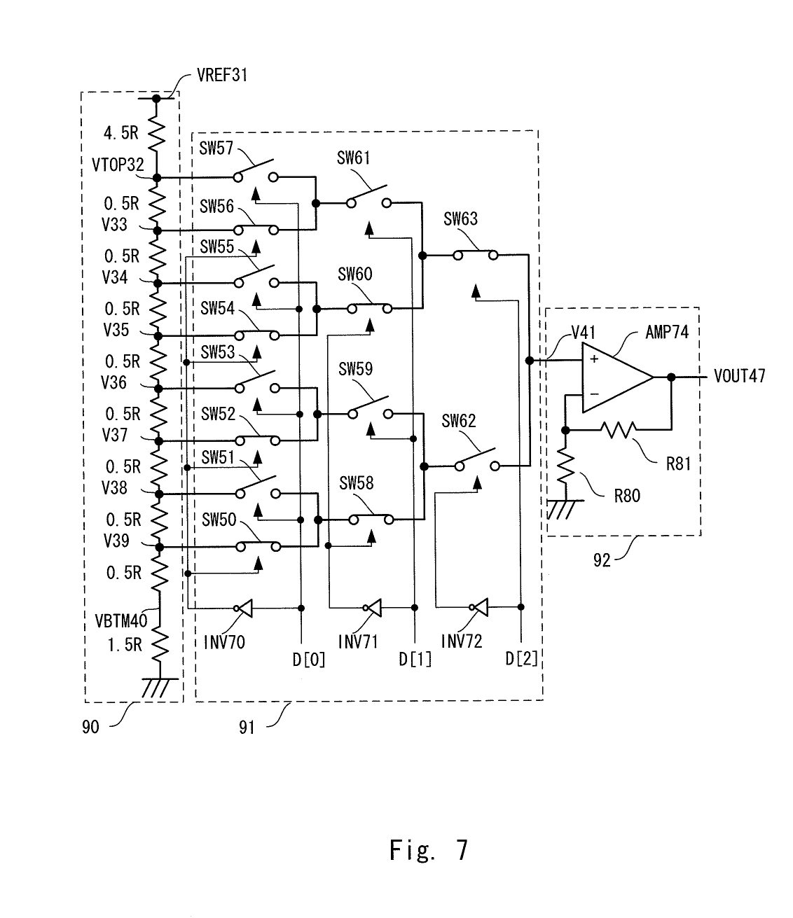

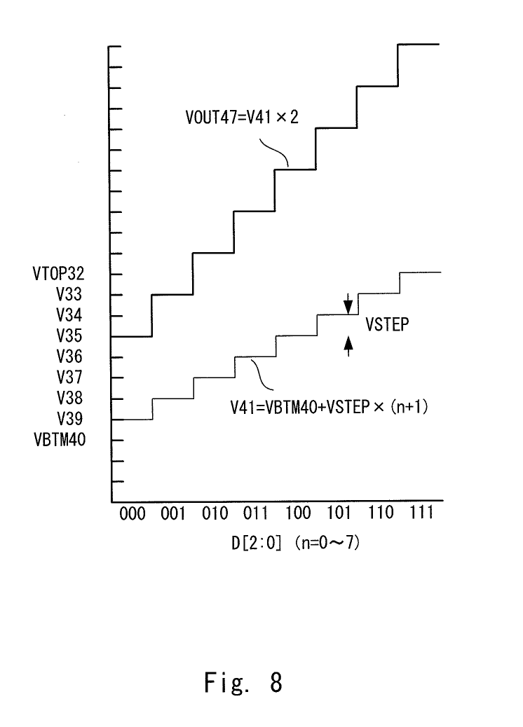

FIG. 2 shows the analog voltage V141 and the output voltage VOUT corresponding to the digital input data in the D-A converter 100 shown in FIG. 1. As shown in FIG. 2, the output voltage corresponding to the digital input data having the most significant bit of “1” can be obtained by adding the output voltage corresponding to the digital input data having the most significant bit of “0” and the intermediate voltage VMID144, and then subtracting the lower limit voltage VBTM140. Although 14 switches are required in the circuit shown in FIG. 7 to obtain the 3-bit D-A converter, only 10 switches are required in the first exemplary embodiment. Further, in the m-bit D-A converter, the voltage step VSTEP and the intermediate voltage VMID are as follows.

VSTEP=(VTOP−VBTM)/2^{m}

VMID=(VTOP−VBTM)/2+VBTM (1)

When n=0 to 2^{m}−1, the output voltage VOUT can be expressed as follows: 1) when n=0 to 2^{(m-1)}−1,

VOUT=VSTEP×(n+1)+VBTM; and

2) when n=2^{(m-1)} to 2^{m}−1,

VOUT=VSTEP×(n−2^{(m-1)}+1)+VBTM+VMID−VBTM=VSTEP×(n−2^{(m-1)}+1)+VMID (2).

Simplifying expression (2) with expression (1) gives the following expression (3).

VOUT=VSTEP×(n+1)+VBTM (3)

Hence, the similar voltage as in the circuit shown in FIG. 7 can be output in the D-A converter 100 according to the first exemplary embodiment.

The number of switches of the m-bit voltage selector in the D-A converter 100 can be expressed as follows.

2^{(m-1)}+2^{(m-2})+ . . . +2¹+4

According to the D-A converter 100, the number of switches of the voltage selector can be reduced by 2^{m}−4 compared with the m-bit D-A converter shown in FIG. 7. Accordingly, the D-A converter can be obtained which can save the circuit size even when multiple bits are used.

For example, in the 8-bit D-A converter, the number of switches is 510 in the circuit as shown in FIG. 7. However, according to the first exemplary embodiment, the number of switches is 258, which means 252 switches can be reduced. The number of switches of the 7-bit D-A converter is 254 in the circuit as shown in FIG. 7. Thus, according to the present invention, the 8-bit D-A converter can be realized in an area corresponding to the 7-bit D-A converter with the circuit as shown in FIG. 7.

As stated above, by adding the output voltage corresponding to the digital input data having the most significant bit of “0” and the intermediate voltage VMID in the output voltage range and subtracting the lower limit voltage VBTM140, the output voltage corresponding to the digital input data having the most significant bit of “1” can be obtained. Therefore, it is possible to reduce the number of switches by 2^{m}−4 to select the voltage which is higher than the intermediate voltage VMID144 with the voltage between the upper limit voltage VTOP132 and the lower limit voltage VBTM140 equally divided into 2^{m}. Accordingly, the D-A converter can be obtained which can save the circuit size even when multiple bits are used. Further, the D-A converter is able to cope with multi-color and low-voltage liquid crystal display panel driving IC.

### Second Exemplary Embodiment

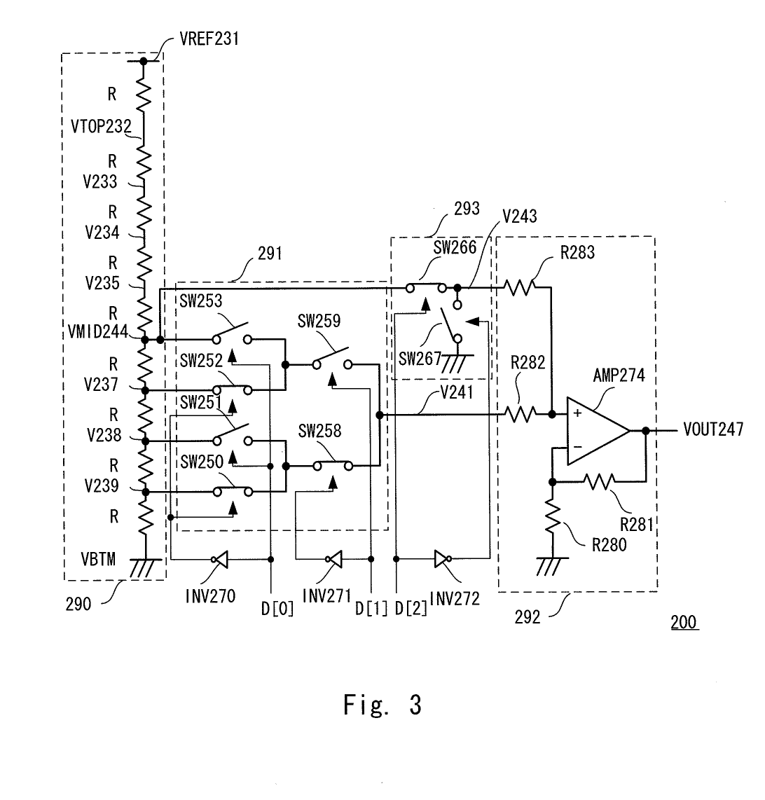

A D-A converter according to a second exemplary embodiment of the present invention will be described with reference to FIG. 3. FIG. 3 shows a configuration of a D-A converter 200 according to the second exemplary embodiment. In the second exemplary embodiment, a 3-bit D-A converter will be described as an example.

As shown in FIG. 3, the D-A converter 200 includes a first selector 291, an amplifier 292, and a second selector 293. Compared with the D-A converter 100 according to the first exemplary embodiment, the D-A converter 200 does not include the third selector that selects and outputs the lower limit voltage VBTM and 0 V in accordance with the digital input data D[2]. Further, the D-A converter 200 includes the amplifier 292 which does not have a subtractor.

The amplifier 292 adds an output voltage V241 from the first selector 291 and an output voltage V243 from the second selector 293. The amplifier 292 includes resistors 8280 to 8283. These resistors 8280 to 8283 have resistance values that are equal to each other. One end of R280 is connected to the ground, and the other end is connected to an inverting input terminal of an operational amplifier AMP274. The resistor 281 is provided between the other end of the resistor 8280 and an output from the operational amplifier AMP274.

In the second exemplary embodiment, digital input data D[1:0] is the lower bit, and D[2] is the higher bit. In the m-bit D-A converter, the voltage step VSTEP and the intermediate voltage VMID are expressed as follows.

VSTEP=VTOP/2^{m}

VMID=VTOP/2 (4)

When n=0 to 2^{m}−1, the output voltage VOUT can be expressed as follows;

1) when n=0 to 2^{(m-1)}−1,

VOUT=VSTEP×n+1); and

2) when n=2^{(m-1)} to 2^{m}−1,

VOUT=VSTEP×(n−2^{(m-1)}+1)+VMID (5).

Simplifying expression (5) with expression (4) gives the following expression (6).

VOUT=VSTEP×(n+1) (6)

As stated above, the similar voltage as in the circuit shown in FIG. 7 can be output also in the D-A converter 200 according to the second exemplary embodiment.

The number of switches of the m-bit voltage selector according to the second exemplary embodiment can be expressed as follows.

2^{(m-1)}+2^{(m-2)}+ . . . +2¹+2

Accordingly, in the circuit according to the second exemplary embodiment, the number of switches of the voltage selector can be reduced by 2^{m}−2 compared with the m-bit D-A converter as shown in FIG. 7.

In the D-A converter 200 according to the second exemplary embodiment, the lower limit voltage VBTM is 0 V. In such a case, the number of switches can be reduced by employing the circuit structure as in the second exemplary embodiment.

### Third Exemplary Embodiment

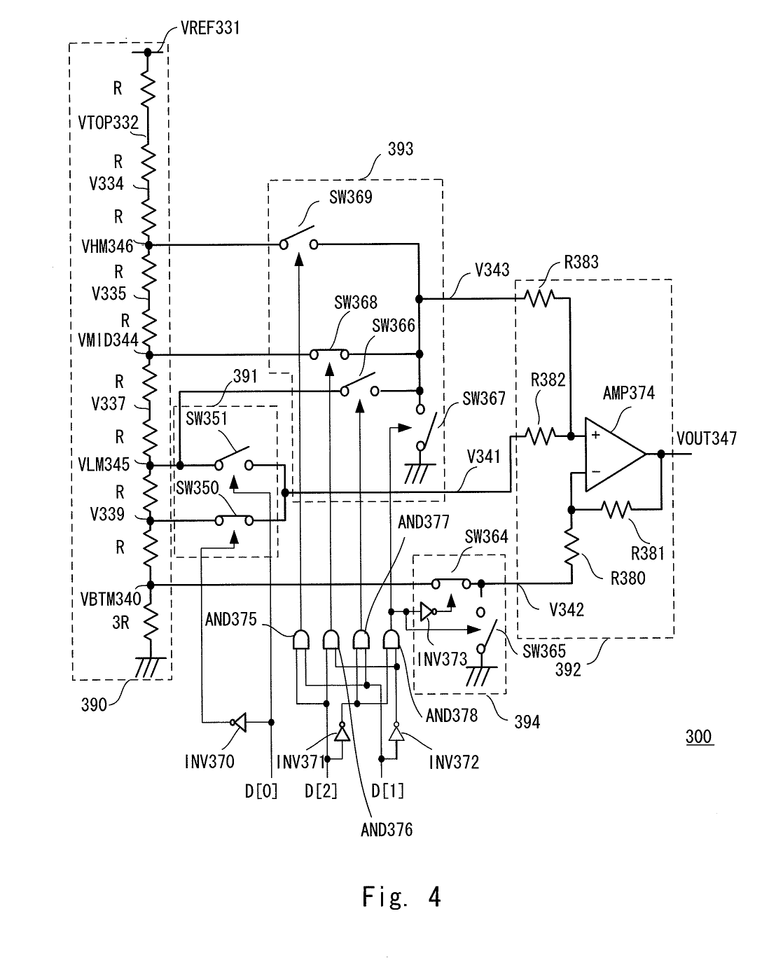

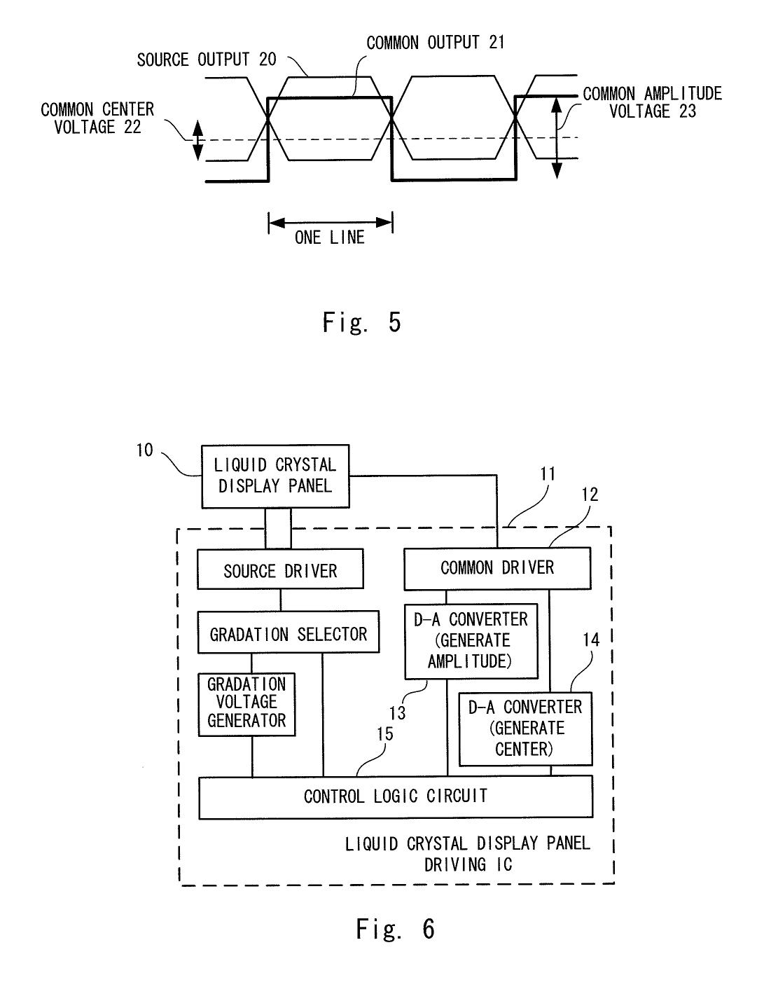

A D-A converter 300 according to a third exemplary embodiment of the present invention will be described with reference to FIG. 4. FIG. 4 shows a configuration of the D-A converter 300 according to the third exemplary embodiment. In the third exemplary embodiment, a 3-bit D-A converter will be described.

As shown in FIG. 4, the D-A converter 300 includes a resistor string 390, a first selector 391, an amplifier 392, a second selector 393, and a third selector 394. The resistor string 390 generates desired upper limit voltage VTOP332 and lower limit voltage VBTM340 from a reference voltage VREF331, evenly divides voltage between the upper limit voltage and the lower limit voltage by eight, so as to obtain an intermediate voltage VMID344, a higher intermediate voltage VHM346, a lower intermediate voltage VLM345, and voltages V334 to V339. Note that the intermediate voltage VMID344 in the third exemplary embodiment corresponds to a middle intermediate voltage.

The resistor string 390 includes 10 resistors connected in series. The reference voltage VREF331 is supplied to one end of the first resistor. The voltage in the node between the first and the second resistors corresponds to the upper limit voltage VTOP332. The ground voltage is supplied to one end of the 10-th resistor. The voltage in the node between the ninth and the tenth resistors corresponds to the lower limit voltage VBTM340.

Further, the voltage in the node between the third and the fourth resistors corresponds to the higher intermediate voltage VHM346. The voltage in the node between the fifth and the sixth resistors corresponds to the intermediate voltage VMID344. The voltage in the node between the seventh and the eighth resistors corresponds to the lower intermediate voltage VLM345.

In summary, the intermediate voltage VMID344 is intermediate between the upper limit voltage VTOP332 and the lower limit voltage VBTM340. The higher intermediate voltage VHM346 is intermediate between the upper limit voltage VTOP332 and the intermediate voltage VMID344, which means the voltage of ¾ between the upper limit voltage VTOP332 and the lower limit voltage VBTM340. The lower intermediate voltage VLM345 is intermediate between the intermediate voltage VMID344 and the lower limit voltage VBTM340, which means the voltage of ¼ between the upper limit voltage VTOP332 and the lower limit voltage VBTM340.

The first selector 391 selects the lower intermediate voltage VLM345 or V339 taken out from the resistor string 390 according to digital input data D[0], and outputs the selected voltage as a voltage V341. In short, the first selector 391 outputs the voltage equal to or lower than the intermediate voltage VLM345 among the plurality of voltages generated in the resistor string 390.

The first selector 391 includes switches SW350 and SW351. Only one path is ON by the digital input data D[0]. The digital input data D[0] is supplied to the switch SW351, and is also supplied to the switch SW350 after being inverted by the inverter INV370.

The second selector 393 selects one of the intermediate voltage VMID344, the higher intermediate voltage VHM346, the lower intermediate voltage VLM345, and the lower power supply voltage (0 V) according to digital input data D[2:1], and outputs the selected one as a voltage V343. The selector 393 includes switches SW366 to SW369.

An output of an AND circuit AND 375 is supplied to the switch SW369. The AND circuit AND375 calculates AND of digital input data D[2] and D[1]. An output of an AND circuit AND376 is supplied to the switch SW368. The AND circuit AND376 calculates AND between the digital input data D[2] and a signal obtained by inverting the digital input data D[1] by an inverter INV372.

An output of an AND circuit AND377 is supplied to the switch SW366. The AND circuit AND377 calculates AND between the signal of the digital input data D[2] inverted by an inverter INV371 and the digital input data D[1]. An output of an AND circuit AND378 is supplied to the switch SW367. The AND circuit AND378 calculates AND of signals obtained by inverting the digital input data D[2] and D[1] by the inverters INV371 and INV372, respectively.

The third selector 394 selects one of the lower limit voltage VBTM340 and 0 V according to the digital input data D[2:1], and outputs the selected one as the voltage V342. The third selector 394 includes switches SW364 and SW365. A signal from the AND circuit AND378 is supplied to the switch SW365, and is also supplied to the switch SW364 after being inverted by an inverter INV373.

The amplifier 392 adds the selected analog voltages V341 and V343, subtracts the voltage V342, and outputs the calculated result as VOUT347. The amplifier 392 includes an operational amplifier AMP374 and resistors R380, R381, R382, and R383. The resistance values of the resistors R380 to R383 are equal to each other. In the third exemplary embodiment, the digital input data D[0] is the lower bit, and D[2:1] is the higher bit.

In the m-bit D-A converter, the voltage step, the intermediate voltage VMID244, the higher intermediate voltage VHM, and the lower intermediate voltage VLM are expressed as follows.

VSTEP=(VTOP−VBTM)/2^{m}

VLM=(VTOP−VBTM)/4+VBTM (7)

VMID=(VTOP−VBTM)/2+VBTM (8)

VHM=(VTOP−VBTM)×¾+VBTM (9) When n=0 to 2^{m}−1, the output voltage VOUT347 can be expressed as follows:

1) when n=0 to 2^{(m-2})−1,

VOUT=VSTEP×(n+1)+VBTM;

2) when n=2^{(m-2)} to 2^{(m-1)}−1,

VOUT=VSTEP×(n−2^{(m-2)}+1)+VBTM+VLM−VBTM=VSTEP×(n−2^{(m-2)}+1)+VLM (10);

3) when n=2^{(m-1)} to 3×2^{(m-2)}−1,

VOUT=VSTEP×(n−3×2^{(m-1)}+1)+VBTM+VMID−VBTM=VSTEP×(n−3×2^{(m-1)}+1)+VMID (11); and

4) when n=3×2^{(m-2)} to 2^{m}−1,

VOUT=VSTEP×(n−3×2^{(m-2)}+1)+VBTM+VHM−VBTM=VSTEP×(n−3×2^{(m-2)}+1)+VHM (12).

Combining expressions (10), (11), and (12) using expressions (7), (8), and (9) gives the following expression (13).

VOUT=VSTEP×(n+1)+VBTM (13)

As shown above, also in the D-A converter 300 according to the third exemplary embodiment, the similar voltage as in the circuit as shown in FIG. 7 can be obtained.

The number of switches of the m-bit voltage selector according to the third exemplary embodiment can be expressed as follows.

2^{(m-2)}+2^{(m-13)}+ . . . +2¹+4+2

According to the third exemplary embodiment, the number of switches of the voltage selector can be reduced by 2^{m}+2^{(m-1)}−6 compared with the m-bit D-A converter shown in FIG. 7. Thus, the D-A converter can be obtained which can save the circuit size even when multiple bits are used.

As described above, according to the present invention, by adding or subtracting between the voltage selected by the lower bit of the digital input data and one or a plurality of intermediate voltages selected by the higher bit, the voltage that deals with all of the digital input data can be output. This enables to reduce the number of switches to select the voltage, to thereby obtain the D-A converter which saves the circuit size even when multiple bits are used. Accordingly, the D-A converter can cope with multi-color and low-voltage liquid crystal display panel driving IC.

Note that the present invention is not limited to the above-described exemplary embodiments, but can be changed as appropriate.

The first to third exemplary embodiments can be combined as desirable by one of ordinary skill in the art.

While the invention has been described in terms of several exemplary embodiments, those skilled in the art will recognize that the invention can be practiced with various modifications within the spirit and scope of the appended claims and the invention is not limited to the examples described above.

Further, the scope of the claims is not limited by the exemplary embodiments described above.

Furthermore, it is noted that, Applicant's intent is to encompass equivalents of all claim elements, even if amended later during prosecution.

What is claimed is:

1. A D-A converter comprising:
a resistor string that generates a plurality of voltages including an upper limit voltage, a lower limit voltage, and an intermediate voltage which is between the upper limit voltage and the lower limit voltage;
a first selector that selects and outputs a first voltage among the plurality of voltages according to a lower bit, the first voltage being selected from the intermediate voltage and a voltage lower than the intermediate voltage;
a second selector that selects and outputs a second voltage according to a higher bit, the second voltage being one of a lower power supply voltage and the intermediate voltage or a voltage higher than the intermediate voltage;
a third selector that selects and outputs a third voltage according to the higher bit, the third voltage being selected from the lower limit voltage and the lower power supply voltage; and
an amplifier that adds the first voltage and the second voltage and subtracts the third voltage, to output an output voltage.

2. A D-A converter comprising:
a resistor string that generates a plurality of voltages including an upper limit voltage, a lower limit voltage, and an intermediate voltage which is between the upper limit voltage and the lower limit voltage;
a first selector that selects and outputs a first voltage among the plurality of voltages according to a lower bit, the first voltage being selected from the intermediate voltage and a voltage lower than the intermediate voltage;
a second selector that selects and outputs a second voltage according to a higher bit, the second voltage being one of a lower power supply voltage and the intermediate voltage or a voltage higher than the intermediate voltage;
an amplifier that adds the first voltage and the second voltage to output an output voltage.

3. The D-A converter according to claim 1, wherein the intermediate voltage is intermediate between the upper limit voltage and the lower limit voltage.

4. The D-A converter according to claim 2, wherein the intermediate voltage is intermediate between the upper limit voltage and the lower limit voltage.

5. The D-A converter according to claim 1, wherein
the intermediate voltage includes a lower intermediate voltage, a middle intermediate voltage which is higher than the lower intermediate voltage, and a higher intermediate voltage which is higher than the middle intermediate voltage,
the first selector outputs the lower intermediate voltage or a voltage lower than the lower intermediate voltage among the plurality of voltages as the first voltage, and
the second selector outputs any one of the higher intermediate voltage, the middle intermediate voltage, the lower intermediate voltage, and the lower power supply voltage as the second voltage.

6. The D-A converter according to claim 5, wherein
the middle intermediate voltage is intermediate between the upper limit voltage and the lower limit voltage;
the higher intermediate voltage is intermediate between the middle intermediate voltage and the upper limit voltage; and
the lower intermediate voltage is intermediate between the middle intermediate voltage and the lower limit voltage.

7. The D-A converter according to claim 1, wherein
the lower bit is a bit other than a most significant bit, and
the higher bit is the most significant bit.
